(19) United States
(12) Patent Application Publication
(10) Pub. No.: US 2009/0166839 A1
(43) Pub. Date: Jul. 2, 2009

(54) SEMICONDUCTOR STACK DEVICE AND MOUNTING METHOD

(75) Inventors: Naoki Suzuki, Osaka (JP); Akihisa Nakahashi, Osaka (JP); Haneo Iwamoto, Osaka (JP); Manabu Gokan, Hyogo (JP); Satoru Yuhaku, Osaka (JP)

Correspondence Address: STEPTOE & JOHNSON LLP, 1330 CONNECTICUT AVE., NW, WASHINGTON, DC, 20036, US

(73) Assignee: Panasonic Corporation, Kadoma-shi (JP)

(21) Appl. No.: 12/342,603

(22) Filed: Dec. 23, 2008

(30) Foreign Application Priority Data
Dec. 28, 2007 (JP) 2007-339167

(51) Int. Cl. H01L 23/48; H01L 21/02

(52) U.S. Cl. 257/686; 438/109; 257/E21.002; 257/E23.169

(57) ABSTRACT

A semiconductor stack device having semiconductor chips stacked therein, wherein pads 4d of an uppermost semiconductor chip 2d are disposed on the side of a base substrate 1, and the pads 4d of the semiconductor chip 2d and electrodes 8d of the base substrate 1 are connected to each other via a flexible substrate 5 having circuit components 7 mounted thereon.

### FIELD OF THE INVENTION

The present invention relates to a semiconductor device mounting method for stacking and mounting semiconductor devices, and a semiconductor stack device.

### BACKGROUND OF THE INVENTION

Memory cards containing memory chips have high portability and thus have been used as record media in portable electronic equipment such as a portable information terminal and a portable phone. Portable electronic equipment has grown in capacity and the need for large-capacity memory cards has also grown, accordingly.

Since the shapes, sizes, and thicknesses of memory cards are specified by common standards, it is necessary to achieve large-capacity memory cards without increasing the sizes.

FIG. 1 in International Publication No. WO 2006/095703 discloses a technique of forming a semiconductor stack device. In this technique, as shown in FIG. 9, a plurality of flexible substrates 202a, 202b, 202c, and 202d each of which has a bare chip 201 mounted thereon are joined via joints 203 at a position out of the mounting region of the bare chips 201, and the flexible substrates are joined to a base substrate 204 via a joint 208, so that the semiconductor stack device is formed.

In a mounting method not using such flexible substrates, semiconductor chips are stacked on a base substrate via adhesive layers and the pads of the semiconductor chips are connected to the electrodes of the base substrate by wire bonding. In this method, the higher semiconductor chip has to be set smaller in size than the lower semiconductor chip to secure the connection region of wires.

In order to avoid this restriction in size, spacers 102a to 102c are used in a method shown in FIG. 7.

A semiconductor chip 101a is bonded on a base substrate 104 via an adhesive layer 103a. On the semiconductor chip 101a, a semiconductor chip 101b is bonded via an adhesive layer 103b, the spacer 102a, and an adhesive layer 103c. On the semiconductor chip 101b, a semiconductor chip 101c is bonded via an adhesive layer 103d, the spacer 102b, and an adhesive layer 103e. On the semiconductor chip 101c, a semiconductor chip 101d is bonded via an adhesive layer 103f, the spacer 102c, and an adhesive layer 103g.

The semiconductor chip 101a is connected to electrodes 106a and 106e of the base substrate 104 via bonding wires 105a and 105e. The semiconductor chips 101b to 101d are similarly connected to electrodes 106b to 106d and 106e to 106h of the base substrate 104 via bonding wires 105b to 105d and 105f to 105h.

The spacers 102a to 102c disposed thus can secure a space for connecting the bonding wires 105a to 105d and 105e to 105h, and prevent contact between upper and lower layers of the semiconductor chips 101a to 101d, so that the semiconductor chips 101a to 101d do not have to be reduced in size with height.

In this method, however, the dimensions are increased by the heights of the spacers 102a to 102c and thus a memory card as a semiconductor stack device is increased in thickness.

In order to address this problem, as shown in FIG. 8, a semiconductor chip 107a is bonded on a base substrate 109 via an adhesive layer 108a and then a semiconductor chip 107b to be bonded on the semiconductor chip 107a via an adhesive layer 108b is laterally displaced from the semiconductor chip 107a. Semiconductor chips 107c and 107d bonded on the semiconductor chips 107a and 107b via adhesive layers 108c and 108d are also laterally displaced. Further, electrodes 111a to hid of the base substrate 109 and pads 110a to 110d of the semiconductor chips 107a to 107d are connected via bonding wires 112a to 112d.

The semiconductor chips 107a to 107d are laterally displaced thus with height, so that a memory card as a semiconductor stack device can be smaller in thickness than in the connecting method of FIG. 7.

### DISCLOSURE OF THE INVENTION

The connecting methods using wire bonding shown in FIGS. 7 and 8 require dimensions for bending up the bonding wires 105d and 112d from the uppermost semiconductor chips 101d and 107d to the base substrates 104 and 109. Thus the completed semiconductor stack devices are increased in thickness, accordingly.

Further, in the connecting methods using wire bonding, circuit components such as a capacitor and a resistor are mounted on the base substrates 104 and 109, thereby increasing the sizes of the base substrates 104 and 109.

The present invention has been devised in view of the problem. An object of the present invention is to provide a semiconductor stack device with a smaller size and thickness and a mounting method thereof.

A semiconductor stack device of the present invention is a semiconductor stack device in which n semiconductor chips are stacked, including: a base substrate having substrate electrodes; the (n−1) semiconductor chips stacked and mounted upward on the base substrate; the uppermost n-th semiconductor chip mounted on the (n−1)th mounted semiconductor chip; bonding wires for electrically connecting the (n−1) semiconductor chips other than the n-th semiconductor chip and the corresponding substrate electrodes of the substrate electrodes of the base substrate; and a flexible substrate for electrically connecting the underside of the n-th semiconductor chip and the corresponding substrate electrode of the substrate electrodes of the base substrate.

Further, the flexible substrate has circuit components mounted thereon.

Moreover, the n semiconductor chips are memory devices.

Further, the semiconductor stack device further includes one of a circuit component and another semiconductor chip in a space surrounded by the base substrate, the flexible substrate, and the stacked semiconductor chips.

A semiconductor stack device of the present invention is a semiconductor stack device in which n semiconductor chips are stacked, including: a flexible substrate having substrate electrodes; the (n−1) semiconductor chips stacked and mounted upward on the flexible substrate; the uppermost n-th semiconductor chip mounted on the (n−1)th mounted semiconductor chip; and bonding wires for electrically connecting the (n−1) semiconductor chips other than the n-th semiconductor chip and the corresponding substrate electrodes of the substrate electrodes of the flexible substrate, wherein the corresponding substrate electrode of the substrate electrodes of the flexible substrate is electrically connected to the underside of the n-th semiconductor chip.

Further, the flexible substrate has circuit components mounted thereon.

Moreover, the n semiconductor chips are memory devices.

A method of mounting semiconductor devices according to the present invention, when n semiconductor chips are stacked and mounted on a base substrate, the method including the steps of: forming a first adhesive layer on the base substrate; stacking the lowermost first semiconductor chip with pads placed face up on the first adhesive layer; repeating, when the semiconductor chips are stacked upward on the first semiconductor chip, the steps of: forming an adhesive layer for mounting the semiconductor chip, on the lower semiconductor chip, and stacking the semiconductor chip with pads placed face up on the formed adhesive layer, and forming an adhesive layer on the (n−1)th semiconductor chip to stack the uppermost n-th semiconductor chip; and stacking the n-th semiconductor chip with pads bonded to a flexible substrate on the adhesive layer formed on the (n−1)th semiconductor chip such that the pads of the n-th semiconductor chip are disposed under the n-th semiconductor chip; respectively bonding the (n−1) semiconductor chips other than the n-th semiconductor chip and the corresponding substrate electrodes of the substrate electrodes of the flexible substrate via bonding wires; and electrically connecting the electrodes of the flexible substrate to the base substrate.

A method of mounting semiconductor devices according to the present invention, when n semiconductor chips are stacked and mounted on a flexible substrate serving as a base substrate, the method including the steps of: forming a first adhesive layer on the flexible substrate; stacking the lowermost semiconductor chip with pads placed face up on the first adhesive layer; repeating, when the semiconductor chips are stacked upward on the lowermost semiconductor chip, the steps of: forming an adhesive layer for mounting the semiconductor chip, on the lower semiconductor chip, and stacking the semiconductor chip with pads placed face up on the formed adhesive layer, and forming the adhesive layer on the (n−1)th semiconductor chip to stack the uppermost n-th semiconductor chip; stacking the n-th semiconductor chip with pads bonded to the flexible substrate on the adhesive layer formed on the (n−1)th semiconductor chip such that the pads of the n-th semiconductor chip are disposed under the n-th semiconductor chip; and respectively bonding the (n−1) semiconductor chips other than the n-th semiconductor chip and the corresponding substrate electrodes of the substrate electrodes of the flexible substrate via bonding wires.

A semiconductor stack device of the present invention is a semiconductor stack device in which n semiconductor chips are stacked, including: a base substrate having substrate electrodes; the (n−1) semiconductor chips stacked and mounted upward on the base substrate; the uppermost n-th semiconductor chip mounted on the (n−1)th mounted semiconductor chip; bonding wires for electrically connecting the (n−1) semiconductor chips other than the n-th semiconductor chip and the corresponding substrate electrodes of the substrate electrodes of the base substrate; and an intermediate substrate for electrically connecting the underside of the n-th semiconductor chip and the corresponding substrate electrode of the substrate electrodes of the base substrate.

Further, the semiconductor stack device further includes one of a circuit component and another semiconductor chip in a space surrounded by the base substrate, the intermediate substrate, and the stacked semiconductor chips.

This configuration can achieve a semiconductor stack device with a smaller size and thickness.

### BRIEF DESCRIPTION OF THE DRAWINGS

FIG. 1A is a sectional view showing a semiconductor stack device according to a first embodiment of the present invention;

FIG. 1B is a sectional view showing a semiconductor stack device according to a second embodiment of the present invention;

FIG. 2 is a process drawing showing a mounting method of the semiconductor stack device according to the first embodiment of the present invention;

FIG. 3 is a sectional view showing a semiconductor stack device according to a third embodiment of the present invention;

FIG. 4 is a process drawing showing a mounting method of the semiconductor stack device according to the third embodiment;

FIG. 5 shows a state before the uppermost semiconductor chip is stacked according to the third embodiment;

FIG. 6A is a sectional view showing a semiconductor stack device according to a fourth embodiment of the present invention;

FIG. 6B is an enlarged perspective view showing an intermediate substrate according to the fourth embodiment;

FIG. 6C is an enlarged perspective view showing an intermediate substrate according to a fifth embodiment of the present invention;

FIG. 7 shows a semiconductor stack device of the prior art;

FIG. 8 shows a semiconductor stack device of the prior art; and

FIG. 9 is a sectional view of International Publication No. WO 2006/095703.

### DESCRIPTION OF THE EMBODIMENTS

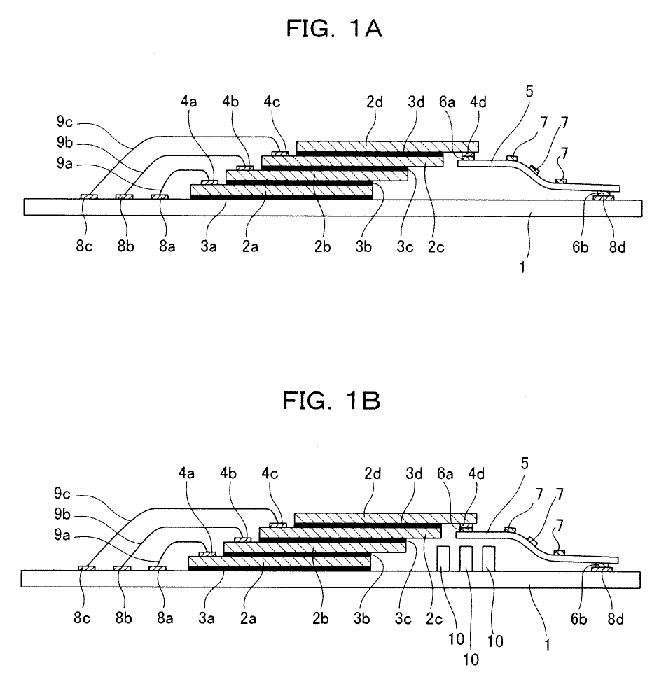

Referring to FIGS. 1 to 5 and FIGS. 6A to 6C, embodiments of the present invention will be described below.

### First Embodiment

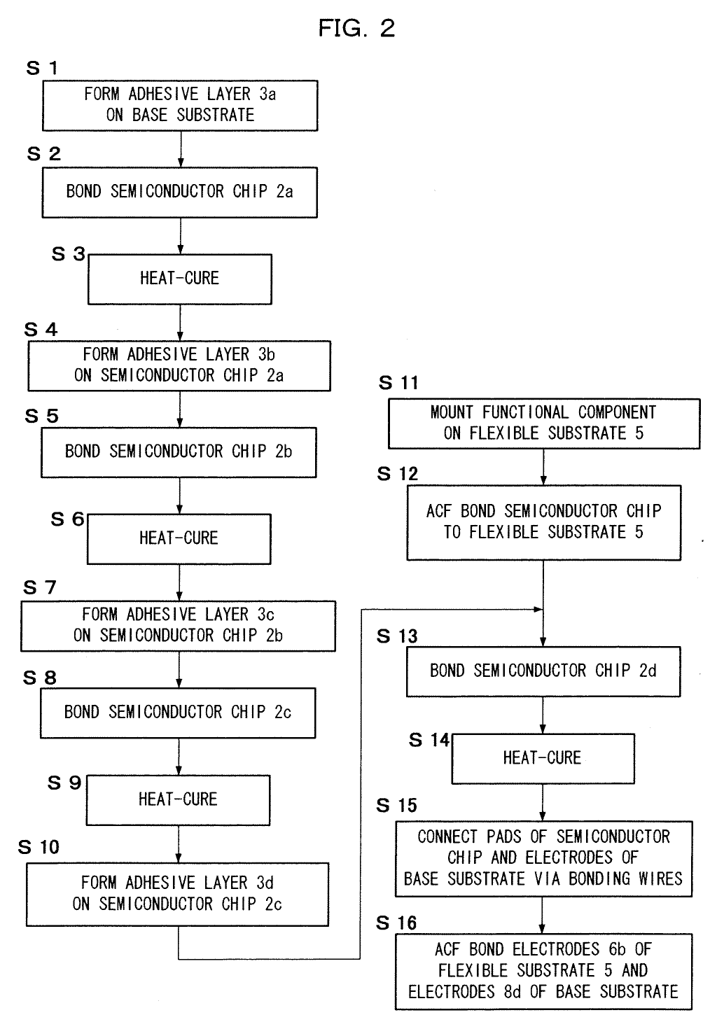

FIGS. 1A and 2 show a first embodiment of the present invention.

In FIG. 1A, a base substrate 1 is composed of a glass epoxy substrate having electrical wiring and includes electrodes 8a, 8b, and 8c. On the base substrate 1, semiconductor chips 2a, 2b, 2c, and 2d are stacked via adhesive layers 3a, 3b, 3c, and 3d while being sequentially displaced in a lateral direction. Provided on one ends of the top surfaces of the semiconductor chips 2a, 2b, and 2c in the stacked state are pads 4a, 4b, and 4c. Provided on one end of the underside of the uppermost semiconductor chip 2d in the stacked state is pads 4d.

To be specific, as shown in step S1 of FIG. 2, a film adhesive is bonded to the base substrate 1 to form the adhesive layer 3a.

In step S2, the semiconductor chip 2a is placed on the adhesive layer 3a.

In step S3, the adhesive layer 3a is heat-cured while the semiconductor chip 2a is pressed to the base substrate 1.

In step S4, a film adhesive is bonded on the semiconductor chip 2a so as to expose the pads 4a, so that the adhesive layer 3b is formed.

In step S5, the semiconductor chip 2b is placed on the adhesive layer 3b.

In step S6, the adhesive layer 3b is heat-cured while the semiconductor chip 2b is pressed to the base substrate 1.

In step S7, a film adhesive is bonded on the semiconductor chip 2b so as to expose the pads 4b, so that the adhesive layer 3c is formed.

In step S8, the semiconductor chip 2c is placed on the adhesive layer 3c.

In step S9, the adhesive layer 3c is heat-cured while the semiconductor chip 2c is pressed to the base substrate 1.

In step S10, a film adhesive is bonded on the semiconductor chip 2c so as to expose the pads 4c, so that the adhesive layer 3c is formed.

On the uppermost semiconductor chip 2d, a flexible substrate 5 is bonded before the semiconductor chip 2d is stacked. To be specific, in step S11, circuit components 7 such as a capacitor and a resistor are mounted beforehand by solder flow on the wiring of the flexible substrate 5.

In step S12, an anisotropic conductive adhesive film (ACF), which is not shown, is bonded to electrodes 6a of the flexible substrate 5. To be specific, metal bumps (not shown) formed on the pads 4d of the semiconductor chip 2d are bonded to the electrodes 6a of the flexible substrate 5.

In step S13, the semiconductor chip 2d is placed on the adhesive layer 3d such that the flexible substrate 5 is disposed on the side of the base substrate 1, and then the semiconductor chip 2d is bonded to the adhesive layer 3d having been formed in step S10.

In step S14, the adhesive layer 3d is heat-cured while the semiconductor chip 2d is pressed to the base substrate 1.

All the semiconductor chips 2a to 2d are stacked thus on the base substrate 1. In step S15, the pads 4a, 4b, and 4c of the semiconductor chips 2a, 2b, and 2c are respectively connected to electrodes 8a, 8b, and 8c of the base substrate 1 via bonding wires 9a, 9b, and 9c.

Further, in step S16, electrodes 6b on the leading end of the flexible substrate 5, which has the base end connected to the uppermost semiconductor chip 2d, are bonded to electrodes 8d of the base substrate 1 via an anisotropic conductive adhesive film by thermocompression bonding.

In this way, the semiconductor chips 2a, 2b, 2c, and 2d are electrically connected to the base substrate 1 via the bonding wires 9a, 9b, and 9c and the flexible substrate 5.

The wiring of the flexible substrate 5 is formed of a flexible sheet like a resin film. In this example, a polyimide film having a thickness of 50 μm was used. When the circuit components 7 are not mounted on the flexible substrate 5, the wiring on the flexible substrate 5 can be simplified to a straight line shape and so on.

Since the electrodes 6a and 6b are provided on both sides of the flexible substrate 5, the wiring can be connected via through holes.

The semiconductor chips 2a to 2d were 100 μm in thickness, the adhesive layers 3a to 3d were 50 μm in thickness, and a thickness on the base substrate 1 was 600 μm.

The anisotropic conductive adhesive is an insulating resin material in which minute conductive metal particles are dispersed. In bonding via the anisotropic conductive adhesive, heat and a pressure are applied while the ACF is interposed between the electrodes, so that the electrodes are electrically and thermally connected to each other via the metal particles and are physically bonded via the cured and constricted resin material.

Moreover, in the present embodiment, the metal bumps are formed only on the pads 4d of the uppermost semiconductor chip 2d to which the anisotropic conductive adhesive film is bonded.

As has been described, the pads 4d of the uppermost semiconductor chip 2d are disposed on the side of the base substrate 1, and the pads 4d of the semiconductor chip 2d and the electrodes 8d of the base substrate 1 are connected to each other via the flexible substrate 5 on which the circuit components 7 are mounted, thereby achieving a smaller and thinner semiconductor stack device.

### Second Embodiment

FIG. 1B shows a second embodiment of the present invention.

The present embodiment is different from FIG. 1A only in that circuit components 10 are mounted in a space between a flexible substrate 5 and a base substrate 1. In this case, the packaging density is improved as compared with the configuration of FIG. 1A. The circuit components 10 include a tall capacitor. Another semiconductor chip may be mounted in the space between the flexible substrate 5 and the base substrate 1.

### Third Embodiment

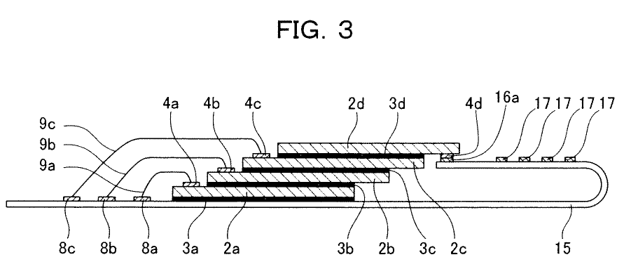

FIGS. 3 to 5 show a third embodiment of the present invention.

In the first embodiment, the semiconductor chips 2a to 2d are mounted on the base substrate 1 made of glass epoxy, and the semiconductor chip 2d and the base substrate 1 are connected to each other via the flexible substrate 5. The third embodiment is different from the first embodiment in that a flexible substrate 15 also serves as a base substrate 1.

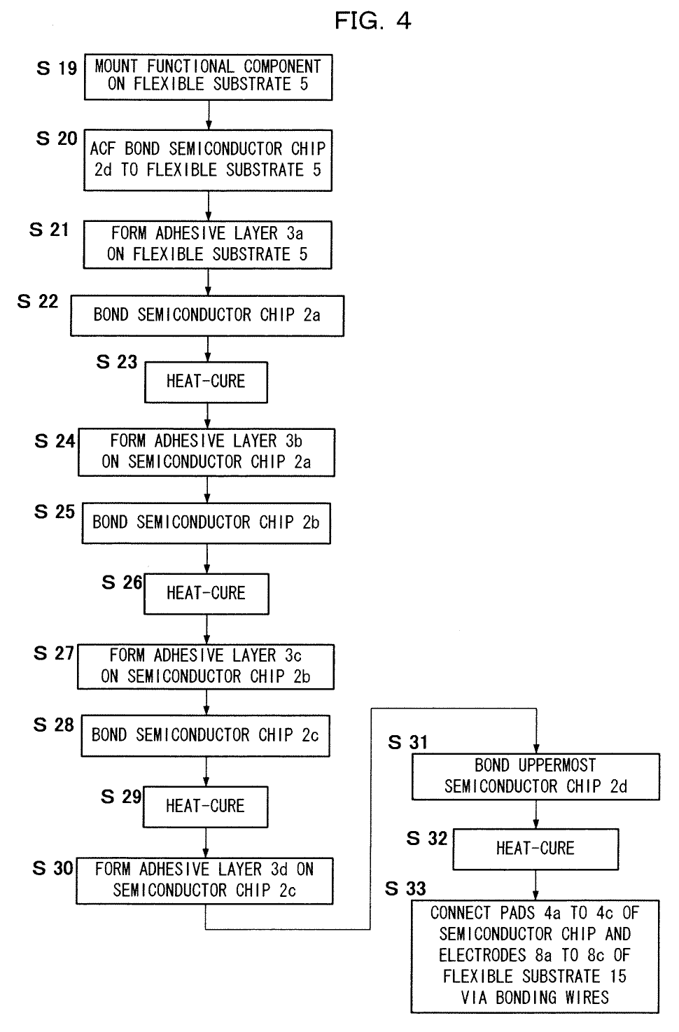

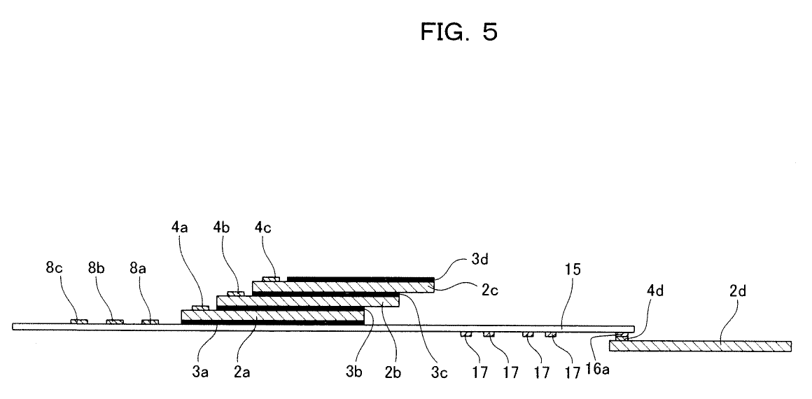

FIG. 3 shows a completed semiconductor stack device. FIG. 4 is a process drawing of a mounting method. FIG. 5 shows a state before the uppermost semiconductor chip is stacked.

In the third embodiment, as shown in FIG. 3, one end of the flexible substrate 15 is bent and electrodes 16a on the one end are connected to pads 4d of a semiconductor chip 2d placed uppermost. The electrodes 16a of the flexible substrate 15 are formed on the opposite side from electrodes 8a to 8c.

In FIG. 4, in steps S21 to S30, semiconductor chips 2a, 2b, and 2c are laterally displaced and stacked on the flexible substrate 15 via adhesive layers 3a, 3b, and 3c as in steps S1 to S10 of FIG. 2. On the semiconductor chips 2a, 2b, and 2c, pads 4a, 4b, and 4c are provided only in one direction.

In step S19 before step S21, circuit components 17 such as a capacitor and a resistor are mounted on the wiring of the flexible substrate 15 by solder flow.

In step S20, as shown in FIG. 5, the pads 4d of the uppermost semiconductor chip 2d are bonded to the electrodes 16a provided on the one end of the flexible substrate 15. To be specific, an ACF is interposed between the pads 4d of the semiconductor chip 2d and the electrodes 16a of the flexible substrate 15, and metal bumps formed on the pads 4d are heated and pressed so as to be bonded to the electrodes 16a of the flexible substrate 15.

In step S31, the flexible substrate 15 is bent to bond the uppermost semiconductor chip 2d on an adhesive layer 3d.

In step S32, the adhesive layer 3d is heat-cured while the semiconductor chip 2d is pressed to the flexible substrate 15.

In step S33, the pads 4a, 4b, and 4c of the semiconductor chips 2a, 2b, and 2c and the electrodes 8a, 8b, and 8c of the flexible substrate 15 are connected via bonding wires 9a, 9b, and 9c, respectively.

The pads 4d of the uppermost semiconductor chip 2d are disposed on the side of the flexible substrate 15, and the flexible substrate 15 having the circuit components 17 mounted thereon also serves as a base substrate, thereby achieving a smaller and thinner semiconductor stack device.

### Fourth Embodiment

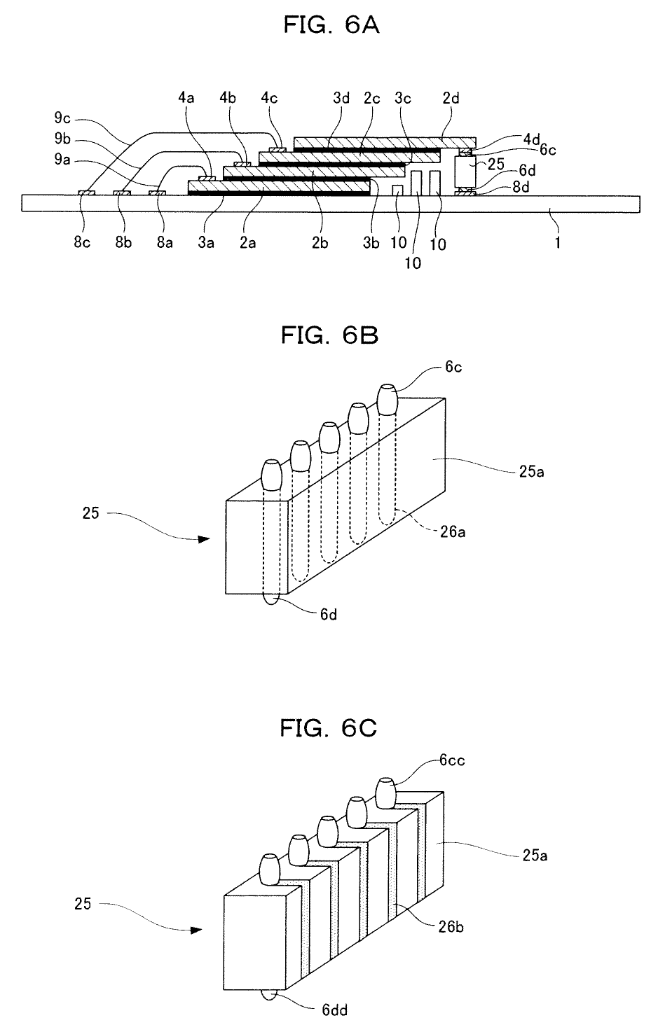

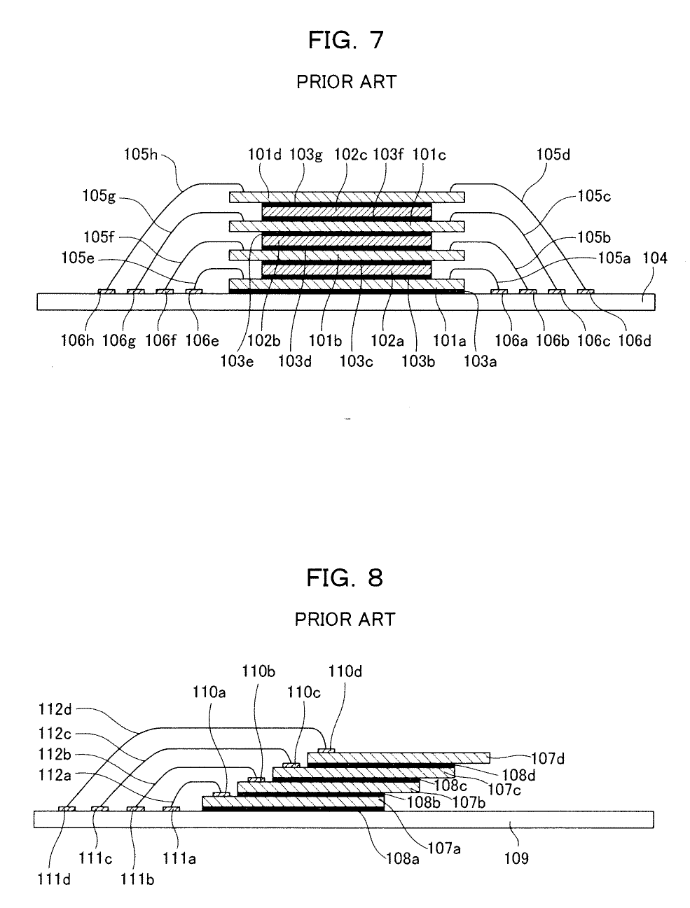

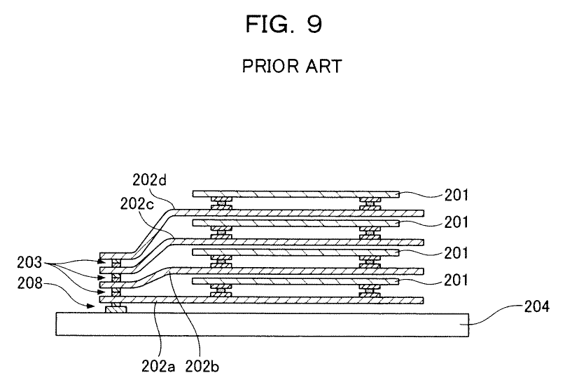

FIGS. 6A and 6B show a fourth embodiment of the present invention.

FIG. 6A is a sectional view showing a semiconductor stack device. FIG. 6B is an enlarged perspective view of an intermediate substrate 25.

The fourth embodiment is a modification of the first embodiment shown in FIG. 1A.

In the first embodiment, the pads 4d of the semiconductor chip 2d and the electrodes 8d of the base substrate 1 are connected to each other via the flexible substrate 5, whereas in the fourth embodiment, a semiconductor chip 2d placed uppermost and a base substrate 1 are connected each other via the intermediate substrate 25. The base substrate 1 has circuit components 10 mounted in a space surrounded by the base substrate 1, semiconductor chips 2b and 2c, and the intermediate substrate 25.

As shown in FIG. 6B, the intermediate substrate 25 is configured such that a plurality of leads 26a are embedded at predetermined spacings into a block 25a which is shaped like a rectangular solid. The leads 26a include ends 6c and 6d which serve as electrodes and are exposed from the top surface and underside of the block 25a. Pads 4d of the semiconductor chip 2d and electrodes 8d of the base substrate 1 are connected to each other via the plurality of leads 26a of the intermediate substrate 25. Any one of methods using conductive paste, solder connection, and an ACF can be used for this connection.

The predetermined spacings between the plurality of the leads 26a are such that spacings between the ends 6c correspond to spacings between the pads 4d of the semiconductor chip 2d and spacings between the ends 6d correspond to spacings between the electrodes 8d of the base substrate 1. The spacings between the ends 6c and the spacings between the ends 6d may be equal or different from each other. The intermediate substrate 25 is mounted on the base substrate 1, for example, when the circuit components 10 are mounted on the base substrate.

This configuration can achieve a packaging structure laterally having a smaller area than in the other embodiments. In other words, the space of the packaging structure has a high usage rate. Other configurations are the same as the other embodiments.

The manufacturing method of the semiconductor stack device is substantially the same as the methods of the first to third embodiments. After the components other than the semiconductor chip 2d are mounted according to the foregoing methods, the semiconductor chip 2d is finally mounted. The semiconductor chip 2d is connected to the semiconductor chip 2c via an adhesive layer 3d. The semiconductor chip 2d is connected to the intermediate substrate 25 via solder paste. The ends 6c of the intermediate substrate 25 are coated with solder paste beforehand, and the pads 4d of the semiconductor chip 2d are bonded on the ends 6c.

### Fifth Embodiment

FIG. 6C shows a fifth embodiment of the present invention.

The intermediate substrate 25 of the fourth embodiment is configured such that the leads 26a are embedded into the block 25a. In the fifth embodiment, electrodes 6cc and 6dd provided on the ends of a block 25a are connected to each other via conductor layers 26b formed on the surfaces of the block 25a. Other configurations are the same as the fourth embodiment.

The foregoing explanation described the embodiments of the present invention. The present invention is not limited to the first to fifth embodiments and can be modified in various ways.

For example, although the four semiconductor chips 2a, 2b, 2c, and 2d are stacked in the foregoing explanation, the present invention can be similarly applied to other configurations by bonding one of the flexible substrates 5 and 15 to the uppermost semiconductor chip, as long as at least two semiconductor chips are stacked.

Further, the semiconductor chips 2a, 2b, 2c, and 2d do not always have to be memory devices. The semiconductor chips may be control devices for controlling memory devices or devices also acting as memory controllers. Moreover, the semiconductor chips do not have to entirely contain semiconductors as long as semiconductors are used in the chips.

In bonding using non-conductive resin, heat is applied to the bumps opposed to the electrodes via the non-conductive resin applied on the electrodes, while the bumps are pressed onto the electrodes. Thus the bumps and the electrodes are brought into contact with each other and are electrically connected. Further, the bumps and the electrodes are physically joined by curing and constricting the non-conductive resin.

It is not always necessary to use an ACF when the semiconductor chip 2d is mounted on the flexible substrates 5 and 15 and when the semiconductor chip 2d is mounted on the base substrate 1. For example, one of a non-conductive film (NCF), non-conductive paste (NCP), and anisotropic conductive adhesive paste (ACP) may be used.

Although the base substrate 1 of glass epoxy was used, a ceramic substrate and a flexible polyimide substrate can be similarly used.

The present invention provides a method of achieving a smaller and thinner circuit package substrate. This method can be used for electrically connecting various circuit components onto a base substrate and is particularly effective for reducing the thicknesses of memory cards and so on.

What is claimed is:

1. A semiconductor stack device in which n semiconductor chips are stacked, comprising:
a base substrate having substrate electrodes;
the (n−1) semiconductor chips stacked and mounted upward on the base substrate;
the uppermost n-th semiconductor chip mounted on the (n−1)th mounted semiconductor chip;
bonding wires for electrically connecting the (n−1) semiconductor chips other than the n-th semiconductor chip and the corresponding substrate electrodes of the substrate electrodes of the base substrate; and
a flexible substrate for electrically connecting an underside of the n-th semiconductor chip and the corresponding substrate electrode of the substrate electrodes of the base substrate.

2. The semiconductor stack device according to claim 1, wherein the flexible substrate has circuit components mounted thereon.

3. The semiconductor stack device according to claim 1, wherein the n semiconductor chips are memory devices.

4. The semiconductor stack device according to claim 1, further comprising one of a circuit component and another semiconductor chip in a space surrounded by the base substrate, the flexible substrate, and the stacked semiconductor chips.

5. A semiconductor stack device in which n semiconductor chips are stacked, comprising:
a flexible substrate having substrate electrodes;
the (n−1) semiconductor chips stacked and mounted upward on the flexible substrate;
the uppermost n-th semiconductor chip mounted on the (n−1)th mounted semiconductor chip; and
bonding wires for electrically connecting the (n−1) semiconductor chips other than the n-th semiconductor chip and the corresponding substrate electrodes of the substrate electrodes of the flexible substrate,
wherein the corresponding substrate electrode of the substrate electrodes of the flexible substrate is electrically connected to an underside of the n-th semiconductor chip.

6. The semiconductor stack device according to claim 5, wherein the flexible substrate has circuit components mounted thereon.

7. The semiconductor stack device according to claim 5, wherein the n semiconductor chips are memory devices.

8. A method of mounting semiconductor devices, when n semiconductor chips are stacked and mounted on a base substrate, the method comprising the steps of:
forming a first adhesive layer on the base substrate;
stacking the lowermost first semiconductor chip with pads placed face up on the first adhesive layer;
repeating, when the semiconductor chips are stacked upward on the first semiconductor chip, the steps of:
forming an adhesive layer for mounting the semiconductor chip, on the lower semiconductor chip, and
stacking the semiconductor chip with pads placed face up on the formed adhesive layer, and
forming an adhesive layer on the (n−1)th semiconductor chip to stack the uppermost n-th semiconductor chip;
stacking the n-th semiconductor chip with pads bonded to a flexible substrate on the adhesive layer formed on the (n−1)th semiconductor chip such that pads of the n-th semiconductor chip are disposed under the n-th semiconductor chip;
respectively bonding the (n−1) semiconductor chips other than the n-th semiconductor chip and corresponding substrate electrodes of substrate electrodes of the flexible substrate via bonding wires; and
electrically connecting electrodes of the flexible substrate to the base substrate.

9. A method of mounting semiconductor devices, when n semiconductor chips are stacked and mounted on a flexible substrate serving as a base substrate, the method comprising the steps of:
forming a first adhesive layer on the flexible substrate;
stacking the lowermost semiconductor chip with pads placed face up on the first adhesive layer;
repeating, when the semiconductor chips are stacked upward on the lowermost semiconductor chip, the steps of:
forming an adhesive layer for mounting the semiconductor chip, on the lower semiconductor chip, and
stacking the semiconductor chip with pads placed face up on the formed adhesive layer, and
forming the adhesive layer on the (n−1)th semiconductor chip to stack the uppermost n-th semiconductor chip;
stacking the n-th semiconductor chip with pads bonded to the flexible substrate on the adhesive layer formed on the (n−1)th semiconductor chip such that pads of the n-th semiconductor chip are disposed under the n-th semiconductor chip; and
respectively bonding the (n−1) semiconductor chips other than the n-th semiconductor chip and corresponding substrate electrodes of substrate electrodes of the flexible substrate via bonding wires.

10. A semiconductor stack device in which n semiconductor chips are stacked, comprising:
a base substrate having substrate electrodes;
the (n−1) semiconductor chips stacked and mounted upward on the base substrate;
the uppermost n-th semiconductor chip mounted on the (n−1)th mounted semiconductor chip;
bonding wires for electrically connecting the (n−1) semiconductor chips other than the n-th semiconductor chip and the corresponding substrate electrodes of the substrate electrodes of the base substrate; and
an intermediate substrate for electrically connecting an underside of the n-th semiconductor chip and the corresponding substrate electrode of the substrate electrodes of the base substrate.

11. The semiconductor stack device according to claim 10, further comprising one of a circuit component and another semiconductor chip in a space surrounded by the base substrate, the intermediate substrate, and the stacked semiconductor chips.
